(19) United States
(12) Patent Application Publication
(10) Pub. No.: US 2008/0023802 A1
(43) Pub. Date: Jan. 31, 2008

(54) SEMICONDUCTOR DEVICE HAVING A SCRIBELINE STRUCTURE FAVORABLE FOR PREVENTING CHIPPING

(75) Inventor: Kazumasa Suzuki, Yokohama-shi (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/782,266

(22) Filed: Jul. 24, 2007

(30) Foreign Application Priority Data
Jul. 24, 2006 (JP) 2006-200942

(51) Int. Cl. H01L 23/544

(52) U.S. Cl. 257/620; 257/E23.179

(57) ABSTRACT

A semiconductor device includes at least one semiconductor chip formed on a wafer and a scribeline provided along an outer circumference of the semiconductor chip. The semiconductor device further includes a chipping prevention wall provided close to a blade area in the scribeline to prevent chipping from advancing when the wafer is diced along the blade area.

### CROSS-REFERENCE TO RELATED APPLICATIONS

This application is based upon and claims the benefit of priority from prior Japanese Patent Application No. 2006-200942, filed Jul. 24, 2006, the entire contents of which are incorporated herein by reference.

### BACKGROUND OF THE INVENTION

1. Field of the Invention

The present invention relates to a semiconductor device. More specifically, the invention relates to a scribeline structure that is favorable for preventing chipping from being caused when a wafer is diced into semiconductor chips by a blade.

2. Description of the Related Art

In the manufacture of semiconductor chips, usually, a wafer is diced along a scribeline by a blade, and a plurality of chips formed on the wafer are separated from each other in accordance with blade areas, thus obtaining the chips at once (see, for example, S. Denda, CQ Publishing Co., Ltd., Latest Semiconductor that is Easy to Understand, “Microscopic World. How are Chips Made? Dicing for Making Chips.,” Ch. 6, pp. 141-142, Dec. 1, 2003, ISBN4-789803628-2.

Recently, there have been wafers including a test element group (TEG) and a mark for monitoring a chip forming process and formed on the scribeline thereof in order to obtain chips. There have also been wafers on which semiconductor chips using a low-dielectric film (low-k film) as an interlayer insulation film are formed.

If the TEG and mark on the scribeline are normally diced, chipping is easily caused by mechanical damage from a blade. It is deemed that this problem occurs since the TEG and mark include a plurality of interlayer films that vary in strength (hardness).

In the fourth-generation complementary metal oxide semiconductor (CMOS) (90 nm CMOS), 107.5 μm is required as a width of the TEG and mark including a width for chipping, in consideration of processing variations. If the mechanical damage becomes more serious at the time of dicing, chipping reaches each end of a chip beyond the TEG and mark areas.

If the number of revolutions of a blade is decreased at the time of dicing or the speed of dicing is decreased, chipping can be prevented to some degree. In this case, however, throughput is decreased, too.

### BRIEF SUMMARY OF THE INVENTION

According to a first aspect of the present invention, there is provided a semiconductor device comprising at least one semiconductor chip formed on a wafer, a scribeline provided along an outer circumference of the semiconductor chip, and a chipping prevention wall provided close to a blade area in the scribeline and configured to prevent chipping from advancing when the wafer is diced along the blade area.

According to a second aspect of the present invention, there is provided a semiconductor device comprising a plurality of semiconductor chips formed on a wafer, a scribeline provided between adjacent ones of the semiconductor chips, a manufacture information management area which is provided on the scribeline as the semiconductor chips are formed, and a chipping prevention wall provided close to a blade area in the scribeline in consideration of processing variations and configured to prevent chipping from advancing when the wafer is diced along the blade area

### BRIEF DESCRIPTION OF THE SEVERAL VIEWS OF THE DRAWING

FIG. 1 is a plan view showing a configuration of a semiconductor device according to a first embodiment of the present invention;

FIG. 2 is a sectional view showing a configuration of a chipping prevention wall in the semiconductor device shown in FIG. 1;

FIG. 3 is a sectional view illustrating a step of forming the chipping prevention wall shown in FIG. 2;

FIG. 4 is a sectional view illustrating a step of forming the chipping prevention wall shown in FIG. 2;

FIG. 5 is a sectional view illustrating a step of forming the chipping prevention wall shown in FIG. 2;

FIG. 6 is a sectional view illustrating a step of forming the chipping prevention wall shown in FIG. 2;

FIG. 7 is a sectional view illustrating a step of forming the chipping prevention wall shown in FIG. 2;

FIG. 8 is a sectional view illustrating a step of forming the chipping prevention wall shown in FIG. 2;

FIG. 9 is a sectional view illustrating a step of forming the chipping prevention wall shown in FIG. 2;

FIG. 10 is a sectional view illustrating a step of forming the chipping prevention wall shown in FIG. 2;

FIG. 11 is a sectional view illustrating a step of forming the chipping prevention wall shown in FIG. 2;

FIG. 12 is a sectional view illustrating a step of forming the chipping prevention wall shown in FIG. 2;

FIG. 13 is an illustration of a case where a wafer is diced into semiconductor chips along a blade area on a scribeline in the semiconductor device shown in FIG. 1;

FIG. 14 is a plan view showing another configuration of the chipping prevention wall shown in FIG. 1;

FIG. 15 is a plan view showing still another configuration of the chipping prevention wall shown in FIG. 1; and

FIG. 16 is a plan view showing yet another configuration of the chipping prevention wall shown in FIG. 1.

### DETAILED DESCRIPTION OF THE INVENTION

Embodiments of the present invention will be described with reference to the accompanying drawings. It should be noted that the drawings are schematic ones and the dimension ratios shown therein are different from the actual ones. The dimensions vary from drawing to drawing and so do the ratios of the dimensions. The following embodiments are directed to a device and a method for embodying the technical concept of the present invention and the technical concept does not specify the material, shape, structure or configuration of components of the present invention. Various changes and modifications can be made to the technical concept without departing from the scope of the claimed invention.

### FIRST EMBODIMENT

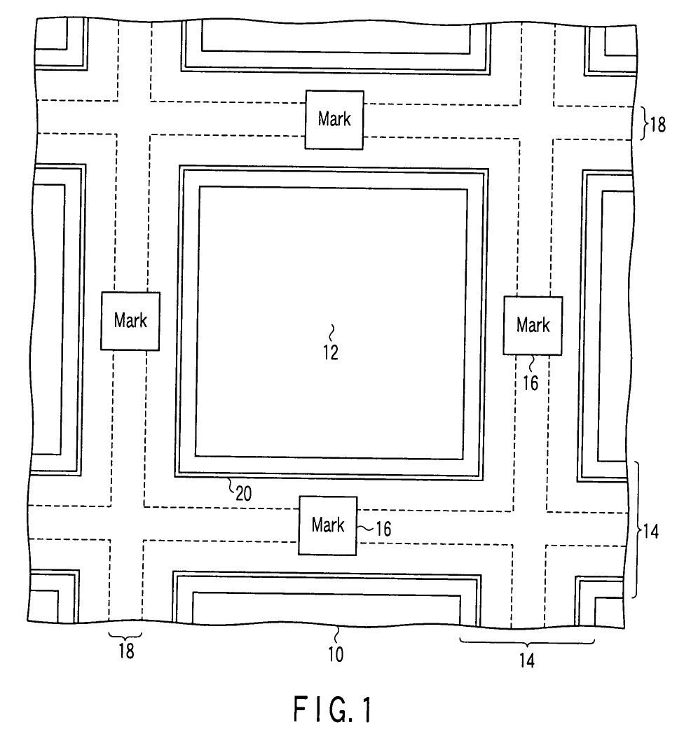

FIG. 1 shows a basic configuration of a semiconductor device according to a first embodiment of the present invention. In the first embodiment, a chipping prevention wall is formed like a ring. The semiconductor device shown in FIG. 1 is an example of a wafer which has not been diced into semiconductor chips.

Referring to FIG. 1, a plurality of semiconductor chips 12 are provided on a wafer (substrate) 10. A scribeline 14 is formed between two semiconductor chips 12. On the scribeline 14, mark areas 16 for a TEG and a mark are formed as manufacturing information management areas. The TEG is used to make a process assessment through the whole process of forming the semiconductor chips 12. The mark is, for example, a mark for Laser Step Alignment (LSA) and a mark for film thickness monitoring, which are used to form the semiconductor chips 12. The TEG and mark are formed when the semiconductor chips 12 are formed.

A ring-shaped chipping prevention wall (chipping ring) 20 is provided on the scribing line 14 so as to surround each of the chips 12. The chipping prevention wall 20 prevents chipping from advancing (spreading) when the wafer 10 is diced and has the same interconnection as that (not shown) of each of the chips 12.

The scribeline 14 has a layered structure in which a plurality of interlayer films of different strengths are stacked including a low-dielectric film (low-k film) (insulation film), and serves as a terminal pad (TP) opening area (passivation film non-forming area) to which a contact pad is exposed from each of the mark areas 16. The scribeline 14 includes a blade area 18 for separating the semiconductor chips 12 from one another when the wafer 10 is diced by means of a blade (not shown).

In the first embodiment, the chipping prevention wall 20 is provided close to the blade area 18 irrespective of the width of the scribeline 14. In other words, the chipping prevention wall 20 is provided in consideration of processing variations such as accuracy variations caused when a wafer is diced by the blade and position variations caused when the mark areas 16 are formed. These variations correspond to the deviation from the center of the scribeline 14 in its width direction. In the case of the fourth-generation CMOS, the width of a mark area including an area for chipping is 107.5 μm is less, and the mark area is arranged within the range of 1 μm to 5 μm outside the blade area 18. Thus, even though chipping is caused by mechanical damage from the blade, its advance (expansion) can be minimized.

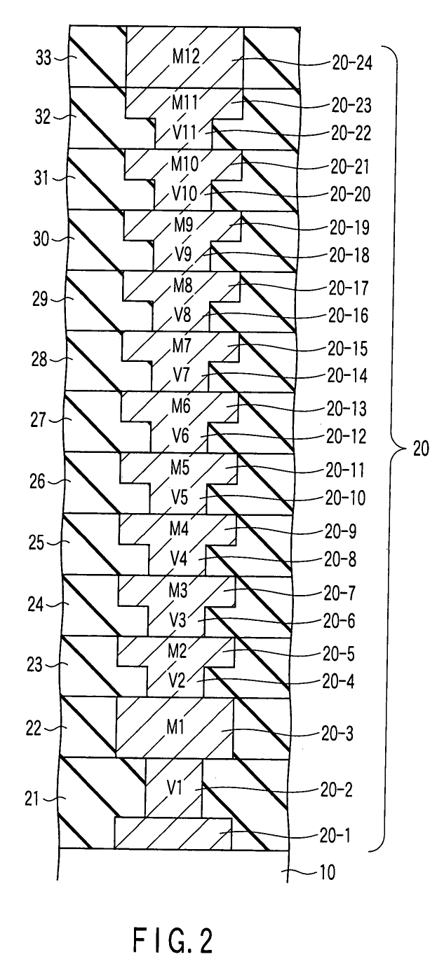

FIG. 2 shows a section of the chipping prevention wall 20 described above. In the first embodiment, the fifth-generation CMOS (65 nm CMOS) (M12-layer product) will be described as one example of the chipping prevention wall.

Referring to FIG. 2, the chipping prevention wall 20 is formed to have the same interconnection as that of the chip 12. More specifically, the chipping prevention wall 20 is configured by a polysilicon layer 20-1, a via (V1) 20-2, an M1 layer 20-3, a via (V2) 20-4, an M2 layer 20-5, a via (V3) 20-6, an M3 layer 20-7, a via (V4) 20-8, an M4 layer 20-9, a via (V5) 20-10, an M5 layer 20-11, a via (V6) 20-12, an M6 layer 20-13, a via (V7) 20-14, an M7 layer 20-15, a via (V8) 20-16, an M8 layer 20-17, a via (V9) 20-18, an M9 layer 20-19, a via (V10) 20-20, an M10 layer 20-21, a via (V11) 20-22, an M11 layer 20-23, and an M 12 layer 20-24, which are stacked one on another in sequence on the substrate 10.

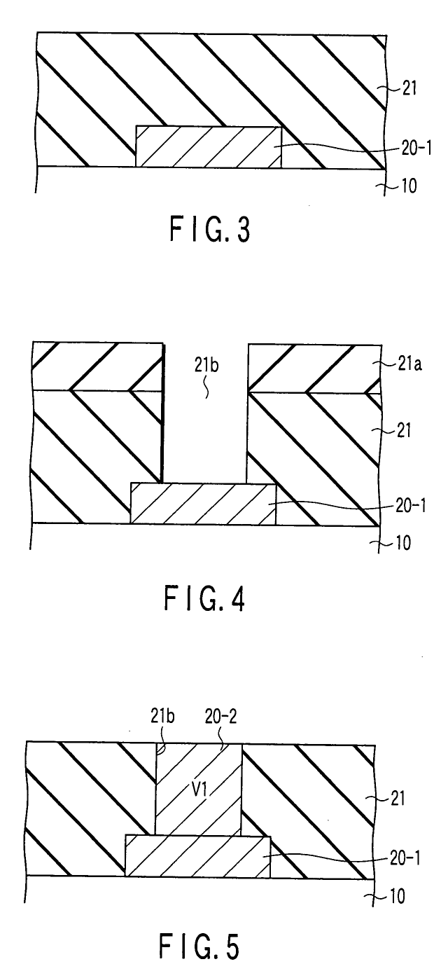

A process of forming the chipping prevention wall 20 will now be described in brief. First, a polysilicon layer 20-1 corresponding to the gate (CS) of a chip 12 is formed on the substrate 10 and then an interlayer film 21 is formed (see FIG. 3, for example). After that, a resist pattern 21a is formed on the interlayer film 21 and, using the resist pattern 21a as a mask, the interlayer film 21 is etched by reactive ion etching (RIE). Thus, an opening 21b is formed in the interlayer film 21 so as to reach the polysilicon layer 20-1 (see FIG. 4, for example). Then, the resist pattern 21a is removed and the opening 21b is filled with conductive materials such as tungsten (W) to form a via (V1) 20-2 corresponding to the gate contact (first via) of the chip 12 (see FIG. 5, for example).

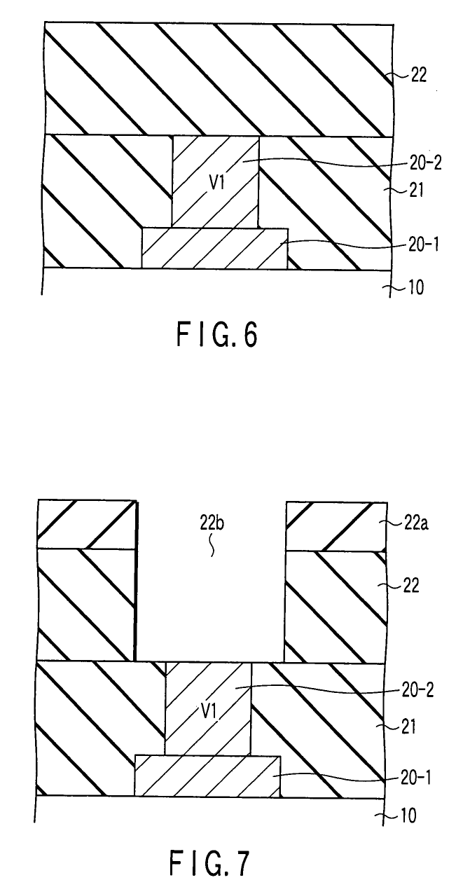

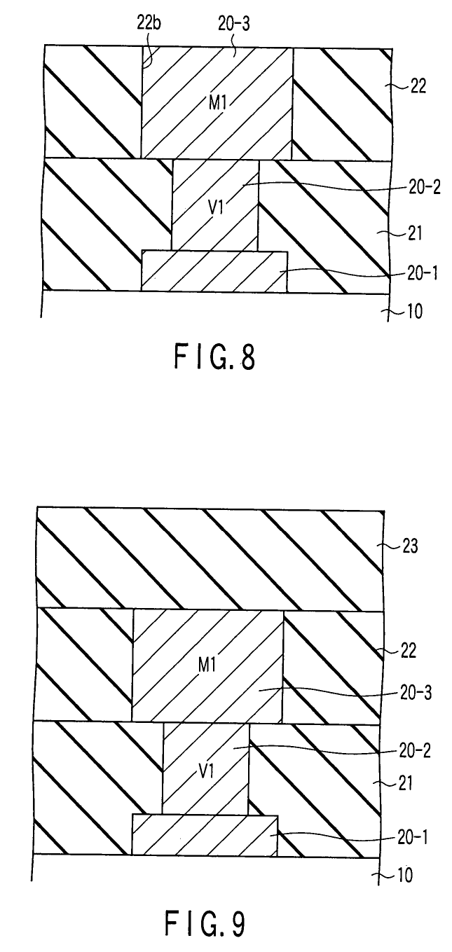

Then, an interlayer film 22 is formed on the top surface of the via (V1) 20-2 as well as the interlayer film 21 (see FIG. 6, for example). Then, a resist pattern 22a is formed on the interlayer film 22 and, using the resist pattern 22a as a mask, the interlayer film 22 is etched by RIE. Thus, an opening 22b is formed in the interlayer film 22 so as to reach the via (V1) 20-2 (see FIG. 7, for example). Then, the resist pattern 22a is removed and the opening 22b is filled with conductive materials such as copper (Cu) to form an M1 layer 20-3 corresponding to a first-layer interconnection (M1L) of the chip 12 (see FIG. 8, for example).

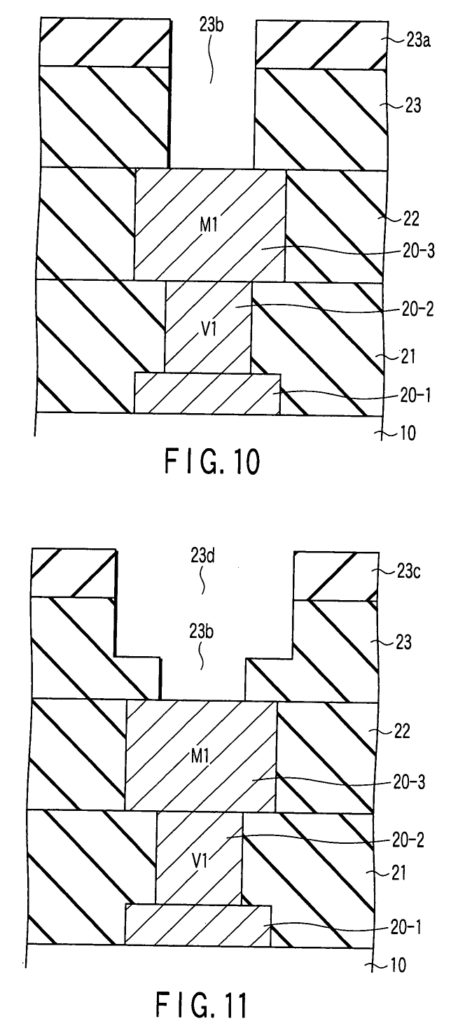

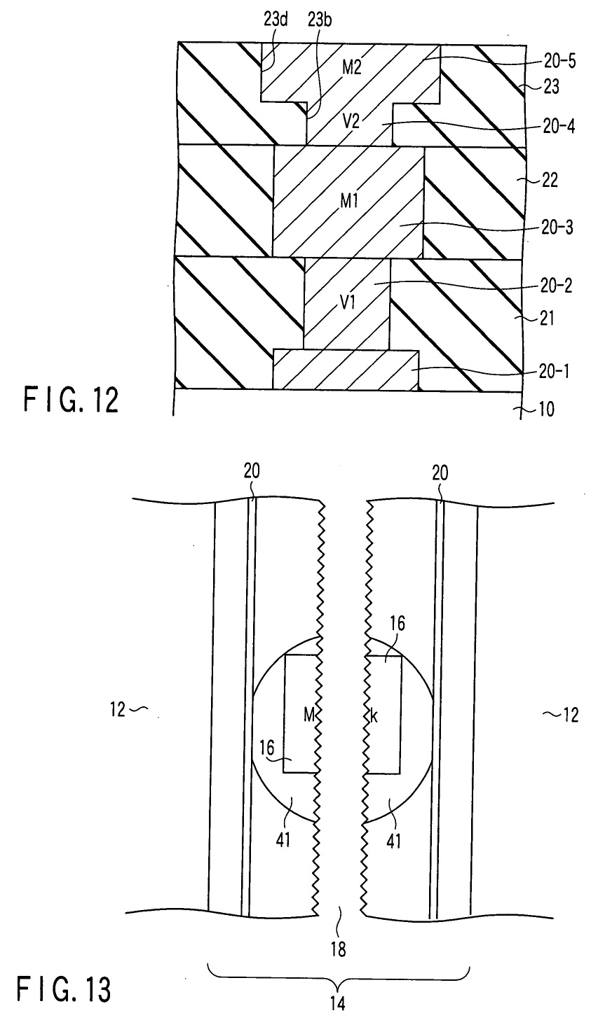

Then, an interlayer film 23 is formed on the top surface of the N1 layer 20-3 as well as the interlayer film 22 (see FIG. 9, for example). Then, a resist pattern 23a is formed on the interlayer film 23 and, using the resist pattern 23a as a mask, the interlayer film 23 is etched by RIE. Thus, a first opening 23b is formed in the interlayer film 23 so as to reach the M1 layer 20-3 (see FIG. 10, for example). The resist pattern 23a is removed and then a resist pattern 23c is formed again on the interlayer film 23. Using the resist pattern 23c as a mask, the interlayer film 23 is etched by RIE. Thus, a second opening 23d is formed in the interlayer film 23 so as to reach the first opening 23b (see FIG. 11, for example). Then, the resist pattern 23c is removed and the first and second openings 23b and 23d are filled with conductive materials such as copper (Cu) to form a via (V2) 20-4 corresponding to a second via of the chip 12 and a an M2 layer 20-5 corresponding to a second-layer interconnection (M2L) thereof (see FIG. 12, for example).

After that, the above process is repeated to form a via (V3) 20-6, an M3 layer 20-7, a via (V4) 20-8, an M4 layer 20-9, a via (V5) 20-10, an M5 layer 20-11, a via (V6) 20-12, an M6 layer 20-13, a via (V7) 20-14, an M7 layer 20-15, a via (VB) 20-16, an M8 layer 20-17, a via (V9) 20-18, an M9 layer 20-19, a via (V10) 20-20, an M10 layer 20-21, a via (V11) 20-22, and an M11 layer 20-23 in sequence. More specifically, an interlayer film 24 is formed on the interlayer film 23 and then a via (V3) 20-6 corresponding to a third via of the chip 12 and an M3 layer 20-7 corresponding to a third-layer interconnection (M3L) thereof are formed. An interlayer film 25 is formed on the interlayer film 24 and then a via (V4) 20-8 corresponding to a fourth via of the chip 12 and an M4 layer 20-9 corresponding to a fourth-layer interconnection (M4L) thereof are formed. An interlayer film 26 is formed on the interlayer film 25 and then a via (V5) 20-10 corresponding to a fifth via of the chip 12 and an M5 layer 20-11 corresponding to a fifth-layer interconnection (M5L) thereof are formed. An interlayer film 27 is formed on the interlayer film 26 and then a via (V6) 20-12 corresponding to a sixth via of the chip 12 and an M6 layer 20-13 corresponding to a sixth-layer interconnection (M6L) thereof are formed. An interlayer film 28 is formed on the interlayer film 27 and then a via (V7) 20-14 corresponding to a seventh via of the chip 12 and an M7 layer 20-15 corresponding to a seventh-layer interconnection (M7L) thereof are formed. An interlayer film 29 is formed on the interlayer film 28 and then a via (V8) 20-16 corresponding to an eighth via of the chip 12 and an M8 layer 20-17 corresponding to an eighth-layer interconnection (M8L) thereof are formed. An interlayer film 30 is formed on the interlayer film 29 and then a via (V9) 20-18 corresponding to a ninth via of the chip 12 and an M9 layer 20-19 corresponding to a ninth-layer interconnection (M9L) thereof are formed. An interlayer film 31 is formed on the interlayer film 30 and then a via (V10) 20-20 corresponding to a tenth via of the chip 12 and an M10 layer 20-21 corresponding to a tenth-layer interconnection (M10L) thereof are formed. An interlayer film 32 is formed on the interlayer film 31 and then a via (V11) 20-22 corresponding to an eleventh via of the chip 12 and an M11 layer 20-23 corresponding to an eleventh-layer interconnection (M11L) thereof are formed.

Finally, an interlayer film 33 is formed and then an M12 layer 20-24 connected to the M11 layer 20-23 and corresponding to a twelfth-layer interconnection (M12L) of the chip 12 is formed of conductive materials such as aluminum (AL). Thus, the chipping prevention wall 20 shown in FIG. 2 is completed.

In the chipping prevention wall, if a twelfth via is provided on the chip 12, a via (not shown) corresponding to the twelfth via and connected to the M11 layer 20-23 is formed before the M12 layer 20-24 is done.

The chipping prevention wall 20 having the same interconnection as that of the chip 12 as in the first embodiment can be formed by the forming process of the interconnection simultaneously with the interconnection of the chip 12. Thus, the chipping prevention wall 20 can be formed with efficiency without adding any specific process.

FIG. 13 shows the semiconductor chip 12 that is diced along the blade area 18 on the scribeline 14. As shown in FIG. 13, the chipping prevention wall 20 is provided close to the blade area 18. Even though chipping 41 is caused by mechanical damage from the blade at the time of dicing, it can be prevented from expanding further and, in other words, the chipping prevention wall 20 can prevent the chipping 41 from expanding. As a result, the chipping 41 can be prevented from reaching each end of the chip 12 without decreasing the rotation speed of the blade or the speed of the dicing.

As described above, the expansion of chipping due to mechanical damage from a blade at the time of dicing can be minimized without a decrease in throughput. In other words, the chipping prevention wall is provided close to the blade area in consideration of processing variations. More specifically, the chipping prevention wall is provided outside the blade area at a distance corresponding to precision variations caused when the wafer is diced by the blade or position variations caused when the mark area is formed. Even though chipping is caused by mechanical damage from the blade, its advance (expansion) can be minimized. If, therefore, the scribeline or mark area has a low-strength interlayer film such as a low-k film, a chip can reliably be protected from damage from dicing without a decrease in throughput.

Particularly when the chipping prevention wall is formed to have the same interconnection of the chip, it can easily be achieved.

Since, moreover, the expansion of chipping does not rely on the structure of the chipping prevention wall or the condition for dicing, no operations for confirming chipping when chip assembly is outsourced are required and accordingly process management is simplified.

In a semiconductor device having a chip ring for protecting a chip from moisture, the chip can reliably be protected from damage from dicing using a chipping prevention wall together with the chip ring. In this case, a chip ring for limiting the width of a scribeline is unnecessary; accordingly, the width of the scribeline can be decreased and the wafer gross can be increased.

In the foregoing first embodiment, a ring-shaped chipping prevention wall (chipping ring) is formed to surround a chip. The present invention is not limited to this chipping ring. Various shapes can be applied to the chipping prevention wall.

### OTHER EMBODIMENTS

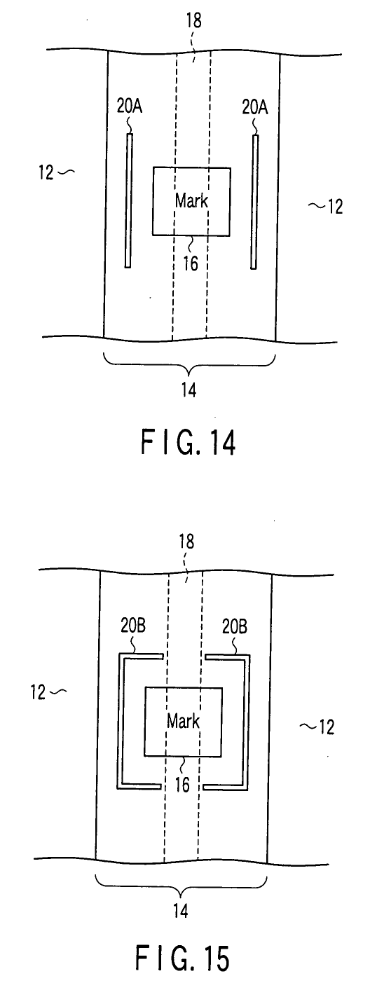

FIG. 14 shows chipping prevention walls 20A each shaped like a line along a scribeline 14. The chipping prevention walls 20A are provided close to the forming position of a mark area 16 and each slightly longer than the mark area 16. The walls 20A extend in a direction perpendicular to the width direction of the scribeline 14. In this embodiment, too, the chipping prevention walls 20A are provided in consideration of processing variations at the time of dicing.

The chipping prevention walls 20A can also bring about almost the same advantage as that in the chipping prevention wall 20 of the first embodiment. In the chipping prevention wall 20A, too, the expansion of chipping can be minimized without a decrease in throughput and thus a chip 12 can be protected from damage from dicing.

FIG. 15 shows U-shaped chipping prevention walls 20B that are provided around a mark area 16. In this embodiment, the chipping prevention walls 20B are provided on a scribeline 14 almost corresponding to the outer circumference of the mark area 16, except at least on a blade area 18. In this embodiment, too, the chipping prevention walls 20B are provided close to the mark area 16 in consideration of processing variations at the time of dicing.

In the chipping prevention walls 20B, too, the expansion of chipping can be minimized without a decrease in throughput and thus a chip 12 can be protected from damage from dicing.

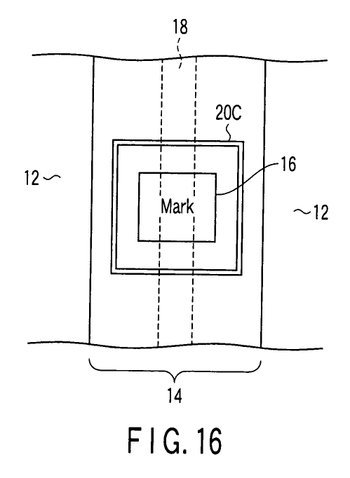

FIG. 16 shows a chipping prevention wall 20C that is provided around a mark area 16. In this embodiment, the chipping prevention wall 20C is provided close to the mark area 16 in consideration of processing variations at the time of dicing.

In the chipping prevention wall 20C, too, the expansion of chipping can be minimized without a decrease in throughput and thus a chip 12 can be protected from damage from dicing.

In each of the embodiments described above, one chipping prevention wall is provided. The present invention is not limited to this. For example, one or more chipping prevention walls can be provided to prevent chipping from advancing with higher reliability.

If the chipping prevention walls 20, 20A, 20B and 20C shown in FIGS. 1 and 14 to 16 are provided in combination, the advantage of preventing chipping from advancing can be increased.

The chipping prevention walls 20, 20A, 20B and 20C each have the same interconnection as that of the chip 12. However, they can be formed to have another structure.

In each of the above embodiments, one mark area 16 is provided between chips 12. However, a plurality of mark areas 16 can be provided.

Needless to say, the semiconductor chips 12 can be applied to various types of semiconductor devices as well as the fourth- and fifth-generation CMOS devices.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
at least one semiconductor chip formed on a wafer;
a scribeline provided along an outer circumference of the semiconductor chip; and
a chipping prevention wall provided close to a blade area in the scribeline and configured to prevent chipping from advancing when the wafer is diced along the blade area.

2. The semiconductor device according to claim 1, wherein the chipping prevention wall is provided in consideration of processing variations.

3. The semiconductor device according to claim 2, wherein the processing variations are precision variations caused when the wafer is diced along the blade area.

4. The semiconductor device according to claim 2, wherein the processing variations are position variations of a manufacture information management area which is provided on the scribeline as the semiconductor chip is formed.

5. The semiconductor device according to claim 1, wherein the blade area has a layered structure of a plurality of interlayer films that are stacked one on another, and the interlayer films include at least insulation films that differ in strength.

6. The semiconductor device according to claim 1, wherein the blade area has a layered structure of a plurality of interlayer films that are stacked one on another, and the interlayer films include at least a low-dielectric film.

7. The semiconductor device according to claim 1, wherein the scribeline has a manufacture information management area thereon, and the chipping prevention wall is provided between the manufacture information management area and the semiconductor chip so as to surround an outer circumference of the semiconductor chip.

8. The semiconductor device according to claim 1, wherein the scribeline has a manufacture information management area thereon, and the chipping prevention wall is provided only between the manufacture information management area and the semiconductor chip.

9. The semiconductor device according to claim 1, wherein the scribeline has a manufacture information management area thereon, and the chipping prevention wall is provided between the manufacture information management area and the semiconductor chip so as to surround an outer circumference of the manufacture information management area.

10. The semiconductor device according to claim 1, wherein the chipping prevention wall has an interconnection that is equal to that of the semiconductor chip.

11. A semiconductor device comprising:
a plurality of semiconductor chips formed on a wafer;
a scribeline provided between adjacent ones of the semiconductor chips;
a manufacture information management area which is provided on the scribeline as the semiconductor chips are formed; and
a chipping prevention wall provided close to a blade area in the scribeline in consideration of processing variations and configured to prevent chipping from advancing when the wafer is diced along the blade area

12. The semiconductor device according to claim 11, wherein the processing variations are precision variations caused when the wafer is diced along the blade area.

13. The semiconductor device according to claim 2, wherein the processing variations are position variations of the manufacture information management area on the scribeline.

14. The semiconductor device according to claim 11, wherein the blade area has a layered structure of a plurality of interlayer films that are stacked one on another, and the interlayer films include at least insulation films that differ in strength.

15. The semiconductor device according to claim 11, wherein the blade area has a layered structure of a plurality of interlayer films that are stacked one on another, and the interlayer films include at least a low-dielectric film.

16. The semiconductor device according to claim 11, wherein the chipping prevention wall is provided between the manufacture information management area and each of the semiconductor chips so as to surround an outer circumference of each of the semiconductor chips.

17. The semiconductor device according to claim 11, wherein the chipping prevention wall is provided only between the manufacture information management area and each of the semiconductor chips.

18. The semiconductor device according to claim 11, wherein the chipping prevention wall is provided between the manufacture information management area and each of the semiconductor chips so as to surround an outer circumference of the manufacture information management area.

19. The semiconductor device according to claim 11, wherein the chipping prevention wall has an interconnection that is equal to that of each of the semiconductor chips.
